(19) United States
(12) Patent Application Publication
(10) Pub. No.: US 2014/0061827 A1
(43) Pub. Date: Mar. 6, 2014

(54) Metal Protection Layer over SiN Encapsulation for Spin-Torque MRAM Device Applications

(71) Applicants: Kenlin Huang, San Jose, CA (US); Yuan-Tung Chin, Fremont, CA (US); Tom Zhong, Saratoga, CA (US); Chyu-Jiuh Torng, Pleasanton, CA (US)

(72) Inventors: Kenlin Huang, San Jose, CA (US); Yuan-Tung Chin, Fremont, CA (US); Tom Zhong, Saratoga, CA (US); Chyu-Jiuh Torng, Pleasanton, CA (US)

(73) Assignee: HEADWAY TECHNOLOGIES, INC., Milpitas, CA (US)

(21) Appl. No.: 13/597,465

(22) Filed: Aug. 29, 2012

(51) Int. Cl. H01L 29/82; H01L 21/8239

(52) U.S. Cl. 257/421; 438/3; 257/E21.645; 257/E29.323

(57) ABSTRACT

A magnetic thin film deposition is patterned and protected from oxidation during subsequent processes, such as bit line formation, by an oxidation-prevention encapsulation layer of SiN. The SiN layer is then itself protected during the processing by a metal overlayer, preferably of Ta, Al, TiN, TaN or W. A sequence of low pressure plasma etches, using Oxygen, Cl₂, BCl₃ and C₂H₄ chemistries provide selectivity of the metal overlayer to various oxide layers and to the photo-resist hard masks used in patterning and metal layer and thereby allow the formation of bit lines while maintaining the integrity of the SiN layer.

### BACKGROUND

1. Technical Field

This disclosure relates generally to magnetic devices that utilize thin film magnetic layers, and more specifically, to methods for protecting such devices during processing.

2. Description of the Related Art

Many present day magnetic devices utilize thin film depositions in which magnetic thin films may have in-plane (plane of deposition) magnetization directions, out-of-plane (i.e., perpendicular to the film plane) magnetization directions, which is often referred to as perpendicular magnetic anisotropy (PMA) or even components in both of such directions. Such devices include, but are not limited to:

(1) various designs of magnetic random access memory (MRAM), e.g., PMA (or Partial-PMA) Spin-Torque MRAM in which such films can serve as pinned layers, reference layers, free layers, or dipole (offset-compensation) layers;
(2) various designs of PMA spin valves, tunnel valves (magnetic tunnel junctions—MTJs) and PMA media used in magnetic sensors and magnetic data storage, and;
(3) other spintronic devices.

In all of these magnetic thin film applications, there is the problem of preventing oxidation of the various metal layers during processing steps that are subsequent to the initial layer depositions and patterning. Often this problem is addressed by encapsulating the depositions with a thin layer of SiN which is an excellent oxidation preventative. Unfortunately, such a layer loses its integrity and/or becomes etched away during subsequent processing steps such as the metal etching processes required for bit line patterning. It would clearly be advantageous to provide a method of protecting thin film depositions from oxidation that would survive the rigors of subsequent processing steps.

Although others have addressed problems associated with the patterning of TJ cells and the incorporation of TJ cells in complex MRAM arrays, these attempts have not dealt with the specific problem of oxidation and its prevention. Gaidis et al. (U.S. Pat. No. 7,825,420), Kim et al. (U.S. Pat. No. 8,092,698) and Wang et al. (U.S. Pat. No. 7,723,128), each describe methods of forming MRAM arrays in which stresses are relieved. As noted, however, none of these methods address the present problem, nor do they utilize the present approach to solving that problem, which will now be described in detail.

### SUMMARY

A first object of the present disclosure is to provide a method of protecting magnetic thin film layered depositions from oxidation during processing steps.

A second object of the present disclosure is to provide such a method that is efficiently incorporated within standard thin film processing methodologies.

A third object of the present disclosure is to provide such a method that is applicable to a wide range of magnetic thin film depositions, including those used in:

(1) various designs of magnetic random access memory (MRAM), e.g., PMA (or Partial-PMA) Spin-Torque MRAM in which such films can serve as pinned layers, reference layers, free layers, or dipole (offset-compensation) layers;
(2) various designs of PMA spin valves, tunnel valves (magnetic tunnel junctions—MTJs) and PMA media used in magnetic sensors and magnetic data storage, and;
(3) other spintronic devices.

The present disclosure describes in detail how these objects are achieved, for example, in the case of the fabrication of a magnetic tunneling junction (TJ) thin film device. In this case, which may be considered as exemplary of the fabrication of other device structures, the protection is provided by means of a metal layer (overlayer) grown on top of a SiN encapsulated TJ thin film deposition. The metal layer protects the integrity of the oxidation-preventive SiN encapsulation layer during subsequent processing steps so that the oxidation protective role of the SiN layer remains continuously effective. The metal overlayer can be a layer of Ta, Al, TiN, TaN or W.

After metal etch and resist stripping (and other such process steps used in bit line patterning), the SiN encapsulation layer remains effectively protected under the metal overlayer that had been formed over it, even during the final step of nitride removal. We find, therefore, that the metal overlayer allows the integrity of the SiN encapsulation layer to be maintained during the subsequent processing steps as was desired. In addition, by means of a novel combination of plasma etching chemistries (Cl₂, BCl₃ and C₂H₄ for a rapid metal etch and a separate O₂ etch for the photo-resist, both in the same chamber), we can obtain good etch selectivities of metal-to-resist and of metal-to-oxide during all process steps. With the combination of metal layer protection and SiN layers the functional properties of the final TJ structure were significantly improved.

### BRIEF DESCRIPTION OF THE DRAWINGS

FIGS. 1a-1f is a sequence of schematic illustrations of the fabrication of an exemplary TJ thin layer deposition using a previous method.

FIGS. 2a-2c is a sequence of schematic illustrations of the fabrication of an exemplary TJ thin layer deposition using the method of the present application.

### DETAILED DESCRIPTION

The present disclosure provides a method for providing continued protection of a thin film deposition against oxidation, such as in protecting a tunneling magnetic junction (TJ) device, during subsequent processing steps. It is to be noted, however, that there is a great variety of thin film depositions that will also be afforded the desired protection using this method. Any deposition in which oxidation prevention layers, such as SiN layers, are applied to exposed surfaces of oxidation-prone layers, are subject to the possibility that the oxidation protection layer will itself be degraded during processing. The present method provides additional protection to the already present oxidation protection layer so that critical regions of that layer receive additional and continual protection.

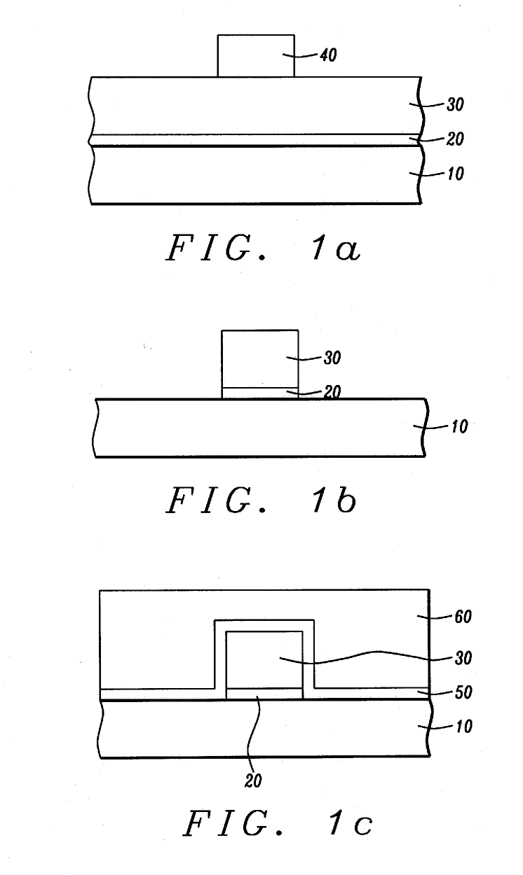

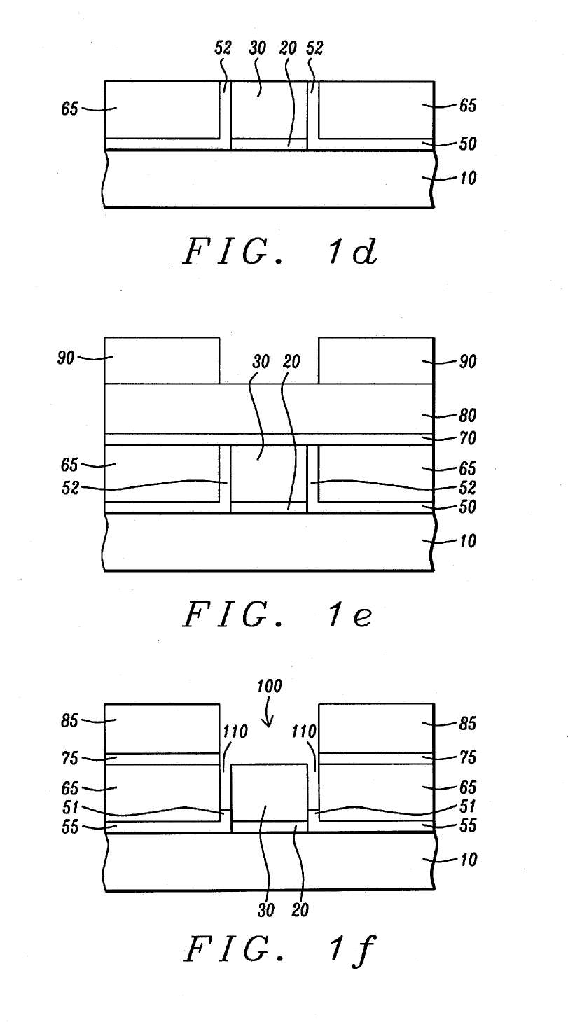

Referring first to FIG. 1a, there is shown a schematic illustration of the first step in the formation of an exemplary TJ structure, such as would be protected by the present method during further processing steps. The structure, which is formed here as three active layers, is shown as not yet being patterned. The structure comprises a lower layer (10) that, in a TJ device, is a magnetic pinned layer, a middle layer (20) that is a tunnel barrier layer (typically a layer of MgO) and an upper layer (30) that is a magnetic free layer. A layer of photoresist, (40), is formed on the upper layer to serve as a patterning mask. The magnetic layers may possess in-plane or out-of-plane magnetic anisotropies and the fabrication may ultimately be used in the spin-torque transfer (STT) type of configuration or the more prevalent field mode configurations. The mode of operation of such a STT fabrication is well known in the art and will not be further described herein.

The structure of FIG. 1a is typically patterned, processed further and equipped with adjacent current carrying lines, such as bit lines, and made a part of a larger structure such as an integrated MRAM circuit.

Referring next to FIG. 1b, there is shown the structure of FIG. 1a, now having been patterned using the photoresist layer ((40) in FIG. 1a) as an etch mask. In this example, the free layer (30) and the tunneling barrier layer (20) are narrowed to some desired critical width by the etch, but this is not a necessary pattern configuration as all three layers could also be patterned to the same critical width. Note, we use the term critical width to denote the desired device width of the completed device.

Referring now to FIG. 1c, there is shown schematically the structure of FIG. 1b with the addition of a thin layer of SiN (50), typically of thickness between 100 and 800 Angstroms formed conformally (over top and against sides) over the free, tunneling and pinned layers, to serve as an encapsulating oxidation protective layer. Note that while SiN will be referred to in this exemplary process, other oxidation prevention encapsulating layers might also be used. A blanket layer of oxide (60), such as a silicon oxide, is then formed over the entire fabrication to provide insulating structure for subsequent fabrications and processes.

Finally, FIG. 1d schematically shows the fabrication of FIG. 1c subsequent to a CMP step (chemical/mechanical polishing) to remove excess oxide ((60) in the previous figure) from the top of the fabrication, leaving oxide remnants (65) to either side of the oxidation prevention SiN layer (50) abutting the free layer (30) and barrier layer (20). The CMP also removes the oxidation prevention SiN layer (50) from the top of the free layer (30), leaving sidewall protective portions (52) abutting the lateral sides of the free and barrier layers. The structure shown in FIG. 1d can be considered a starting step for the present process of forming a bit line. We will first indicate the typical results of using the “old” method as compared with further processing using the present method.

### Old Method

We begin by preparing the fabrication of FIG. 1d for the additional process steps leading to the formation of an overhead bit line. Referring to schematic FIG. 1e, we show the following additional layer depositions that would be required. First, a second SiN oxidation protective encapsulation layer (70) is formed over the CMP smoothed surface of FIG. 1d. Next, a second blanket oxide layer (80), such as formed the first blanket layer (60), is formed over the second SiN layer (70). Finally, photoresist pattern masks (90) are formed, using (for example) an oxygen plasma etch to pattern a layer of photoresist, over the blanket oxide layer in preparation for the bit line trench.

Referring now to FIG. 1f, there is shown the trench (100) etched through the patterned photoresist mask that has removed an appropriate portion of second oxide layer ((80) in FIG. 1e) to leave remaining side portions (85). In addition, second SiN oxidation protection layer ((70) in FIG. 1e) has been partially etched away, leaving remaining portions (75). What is most disturbing, however, is that portions of the oxidation protection sidewall ((52) in FIG. 1d), formed by first SiN layer (50), have been removed by the etch, leaving voids (110) above the remnants (51). The voids (110) are indicative of the loss of protection by the SiN layer, that was the problem to be addressed by this application. We will now indicate how the present application deals with this problem of SiN protection loss.

### New Method

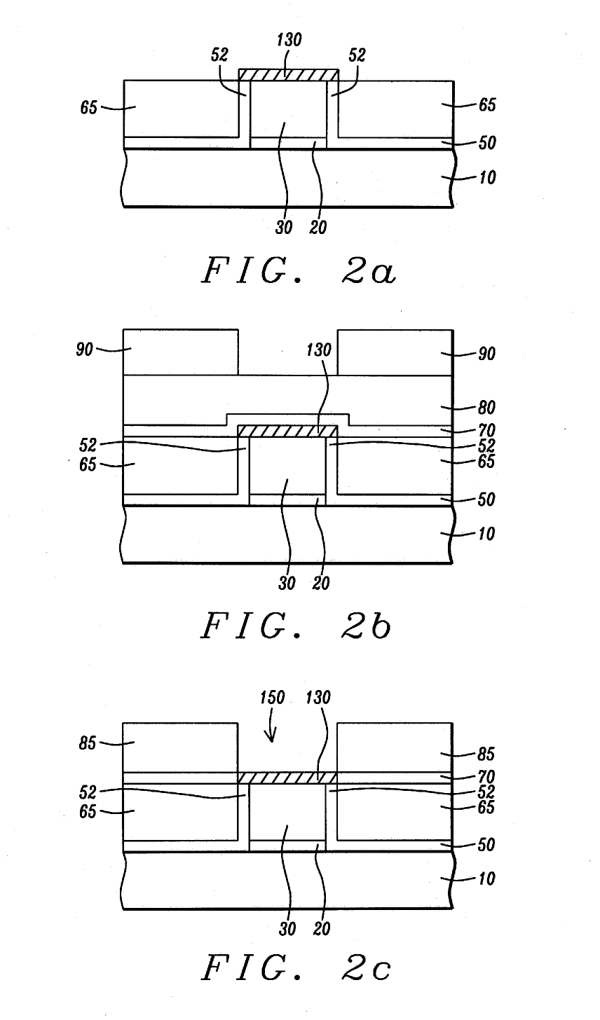

Referring now to FIG. 2a there is shown the fabrication of FIG. 1d, as a starting point, with the new addition of a metal overlayer (130) formed over the CMP smoothed surface. The metal overlayer has been patterned to cover the top surface of the free layer (30) and to exceed the critical width of the patterned device sufficiently to overhang the upper edges (52) of the oxidation protection SiN sidewalls formed by the first SiN layer (50). The metal overlayer is a layer of Ta, Al, TiN, Ti, TaN or W and is typically formed to a thickness between approximately 100 and 300 Angstroms. It is important that the metal layer have a greater lateral width than the critical dimension of the TJ structure (eg. the patterned width of the free layer) so that the oxidation protection SiN sidewalls (52) are adequately protected. In general the metal overlayer is deposited to an excess width and then etched back to the proper width by a suitable hard-masked etch and an etchant that is selective for the metal over the surrounding materials.

Referring now to FIG. 2b, there is shown the fabrication of FIG. 2a with the addition of a second SiN oxidation protective layer (70) formed conformally over the top surface and the extra metal layer (130). A second blanket oxide layer (80) is now deposited over the SiN layer (70) and a photoresist mask (90) is formed over the oxide layer (70) and patterned, for example, by an oxygen plasma.

Referring finally to FIG. 2c, there is shown the fabrication of FIG. 2b with an etch having been performed to create a trench (150) for a bit line deposition. Note that this bit line etch has removed an appropriate section of blanket oxide (80), leaving side sections (85). The bit line etch has also removed the portion of second oxidation protection layer (70) that had been covering the metal overlayer, but has left the metal overlayer (130) itself. During this bit line etch, the metal overlayer protects the upper surface of free layer (30) from that etch and also provides protection to the sidewalls (52) of the first SiN layer. Referring back to FIG. 1f, for comparison, the sidewalls have been partially destroyed (see voids (110) in FIG. 1f) because they lacked the protection of the metal overlayer.

The process steps used to pattern the metal overlayer and then to etch the bit line trench opening while leaving the metal overlayer intact, are carried out in a single chamber and involve the patterning of the metal layer and the removal of the second SiN layer (70) by a combination of plasma chemistries comprising oxygen, Cl₂, BCl₃ and C₂H₄ at low pressures. These chemistries allow precise removal of the metal overlayer to create the proper width of the overlayer (sufficiently exceeding the critical width) and to strip away the resist mask used to pattern the metal overlayer. The chemistries are selective for rapid removal of the metal protective overlayer against the SiN encapsulation layer. A separate oxygen plasma etch, in the same chamber, is used to strip away the remaining photoresist of the photolithographic mask used for patterning the free layer, the oxygen etch being selective for the photoresist as against the magnetic free layer. The photo-resist stripping process provides very good selectivities over the metal and the oxide. The specific details of the plasma chemistries is not given herein beyond the mention of exemplary chemistries that fulfilled the desired selectivities.

As is finally understood by a person skilled in the art, the detailed description given above is illustrative of the present disclosure rather than limiting of the present disclosure. Revisions and modifications may be made to methods, materials, structures and dimensions employed in forming and providing an oxidation-protected encapsulated thin film structure further protected by an additional metal overlayer to maintain integrity of the encapsulation during subsequent processing steps, while still forming and providing such a structure in accord with the spirit and scope of the present invention as defined by the appended claims.

What is claimed is:

1. A method of forming a magnetic thin film device, comprising:
providing a thin film deposition;
patterning said thin film deposition to a critical width;
depositing a first encapsulation layer conformally over a top surface and side surfaces of said patterned deposition, said encapsulation layer being an oxidation prevention layer, and said encapsulation layer forming, thereby, oxidation prevention protective sidewalls against said side surfaces of said patterned deposition;
forming a first blanket oxide layer over said first encapsulation layer;
removing, by a polishing process, an upper portion of said blanket oxide layer and an upper portion of said encapsulation layer, thereby creating a planar surface, said planar surface including upper surfaces of said oxide layer and upper edge surfaces of a remaining portion of said protective sidewalls symmetrically disposed about the exposed top surface of said patterned thin film deposition; then
forming a protective metal overlayer on said planar surface, wherein said protective metal overlayer covers said top surface of said patterned thin film deposition and extends laterally and symmetrically beyond said upper edge surfaces of a remaining portion of said protective sidewalls and thereby protects and insures the integrity of said remaining sidewalls portion of said encapsulation layer during subsequent process steps.

2. The method of claim 1 wherein said first encapsulation layer is a layer of SiN formed to a thickness of between approximately 100 and 800 Angstroms.

3. The method of claim 1 wherein said protective metal overlayer is a layer of Ta, Al, TiN, Ti, TaN or W and it is formed to a thickness of between approximately 100 and 300 Angstroms.

4. The method of claim 1 wherein said protective metal overlayer is formed to a width exceeding said critical dimension of said patterned thin film deposition by a method comprising:
forming a layer of metal conformally over said coplanar surface;
patterning said layer to said width that exceeds said critical width using a photoresistive hard mask formed on said metal layer wherein said hard mask has said width that exceeds said critical width;
etching away portions of said layer of metal laterally extending beyond said photoresistive hard mask using a first selective plasma etch having a plasma chemistry selective for removing said layer of metal while not removing surrounding material; then
removing said photoresistive hard mask using an oxygen plasma.

5. The method of claim 1 further including the formation of a bit line trench by a method comprising:
forming a second oxidation protection encapsulation layer conformally over said coplanar surface and said metal overlayer;
forming a second blanket oxide layer over said second oxidation protection encapsulation layer;
forming a photoresistive patterning mask on said second blanket oxide layer wherein said patterning mask has an opening whose width is at least as wide as said metal overlayer;
using a second selective plasma etch, etching through said patterning mask opening to remove portions of said second oxide layer beneath said opening, removing also said second oxidation preventing encapsulation layer over said metal overlayer and exposing, thereby, said metal overlayer which is not removed by said second selective plasma etch and continues to protect sidewall remnants of said first oxidation preventing encapsulation layer.

6. The method of claim 5 wherein said first and second selective plasma etches comprise combinations of Cl₂, BCl₃ and C₂H₄ plasma chemistries at low pressures.

7. The method of claim 6 wherein said combinations are chosen to be either selective for said metal overlayer as compared to said first encapsulating layer and said blanket oxide layer or to be selective for said second encapsulating layer and said second oxide layer as compared to said metal overlayer.

8. The method of claim 1 wherein said thin film deposition is a TJ deposition comprising a pinned layer, a tunneling barrier layer formed on said pinned layer and a free layer formed on said tunneling barrier layer.

9. The method of claim 1 wherein said thin film deposition includes various designs of magnetic random access memory (MRAM) including those having layers that exhibit perpendicular magnetic anisotropy (PMA or Partial-PMA) Spin-Torque MRAM, in which such layers can serve as pinned layers, reference layers, free layers, or dipole (offset-compensation) layers.

10. An oxidation protected patterned TJ thin film device comprising:
a pinned layer;
a tunneling barrier layer formed on said pinned layer;
a free layer formed on said tunneling barrier layer; wherein
at least said free layer and said tunneling barrier layer are patterned to a critical width; and
oxidation protection sidewalls formed abutting lateral sides of said patterned layers; and
a metal overlayer formed over said free layer and extending laterally beyond said critical width of said free layer whereby said metal overlayer protects said oxidation protection sidewalls.

11. The device of claim 10 wherein said metal overlayer is a layer of Ta, Al, TiN, Ti, TaN or W and it is formed to a thickness of between approximately 100 and 300 Angstroms.

12. The device of claim 10 wherein said oxidation protection sidewalls are formed of SiN to a thickness between 100 and 800 Angstroms.
